(19) United States
(12) Patent Application Publication
(10) Pub. No.: US 2025/0364257 A1
(43) Pub. Date: Nov. 27, 2025

(54) SUBSTRATE GRINDING TOOL AND METHODS OF OPERATION

(71) Applicant: Taiwan Semiconductor Manufacturing Company, Ltd., Hsinchu (TW)

(72) Inventors: Chi-Fan CHEN, Taoyuan City (TW); Chun-Kai LAN, Hsinchu City (TW); Zhen Yu GUAN, Changhua County (TW); Hsun-Chung KUANG, Hsinchu City (TW); Cheng-Yuan TSAI, Chu-Pei City (TW); Chung-Yi YU, Hsin-Chu (TW)

(21) Appl. No.: 19/293,412

(22) Filed: Aug. 7, 2025

Related U.S. Application Data
(62) Division of application No. 18/326,494, filed on May 31, 2023.
(60) Provisional application No. 63/492,678, filed on Mar. 28, 2023.

(51) Int. Cl. H01L 21/306; B24B 1/00; B24B 37/04; B24B 37/16; H01L 21/321

(52) U.S. Cl. CPC H01L 21/30625; B24B 1/00; B24B 37/042; B24B 37/044; B24B 37/16; H01L 21/3212

(57) ABSTRACT

A substrate grinding tool is configured to remove material from a semiconductor substrate in a grinding operation. In the grinding operation, the substrate grinding tool uses a combination of mechanical grinding and a chemical etchant to remove material from the semiconductor substrate. The chemical etchant may be heated to a high temperature, which may increase the etch rate of the chemical etchant. The use of the combination of mechanical grinding and the chemical etchant may increase the grinding rate of the substrate grinding tool for grinding semiconductor substrates, may reduce surface roughness for semiconductor substrates that are processed by the substrate grinding tool, and/or may reduce surface damage for semiconductor substrates that are processed by the substrate grinding tool, among other examples.

### CROSS-REFERENCE TO RELATED APPLICATIONS

This Patent Application is a divisional of U.S. patent application Ser. No. 18/326,494, filed on May 31, 2023, and entitled “SUBSTRATE GRINDING TOOL AND METHODS OF OPERATION,” which claims priority to U.S. Provisional Patent Application No. 63/492,678, filed on Mar. 28, 2023, and entitled “SUBSTRATE GRINDING TOOL AND METHODS OF OPERATION.” The disclosures of the prior Applications are considered part of and are incorporated by reference into this Patent Application.

### BACKGROUND

A manufacturing process of a semiconductor substrate (e.g., a silicon wafer and/or another type of semiconductor substrate) may include a grinding operation in which a substrate grinding tool removes material from semiconductor substrate to reduce the thickness of the semiconductor substrate. In some cases, the grinding operation may be performed to achieve a relatively small final packaged height of a semiconductor device in which the semiconductor substate is included. The grinding operation may be referred to as a backside grinding operation in that the substrate grinding tool removes material from backside of the semiconductor substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example substrate grinding tool described herein.

FIGS. 2A-2E are diagrams of an example implementation of a grinding operation described herein.

FIGS. 3A-3D are diagrams of another example implementation of a grinding operation described herein.

FIGS. 4A-4D are diagrams of another example implementation of a grinding operation described herein.

FIG. 5 is a diagram of an example implementation of an etch rate of a chemical etchant for use in the substrate grinding tool described herein.

FIG. 6 is a diagram of an example implementation of a grind rate of the substrate grinding tool described herein.

FIG. 7 is a diagram of example implementations of surface roughness for semiconductor substrates processed by the substrate grinding tool described herein.

FIGS. 8A and 8B are diagrams of example implementations of surface roughness for semiconductor substrates processed by the substrate grinding tool described herein.

FIG. 9 is a diagram of example components of one or more devices described herein.

FIG. 10 is a flowchart of an example process associated with a grinding operation.

FIG. 11 is a flowchart of an example process associated with a grinding operation.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A substrate grinding tool may include a platen that is configured to support a semiconductor substrate, and a grinding wheel on which an abrasive (e.g., a diamond abrasive and/or another type of abrasive) is included for removing material from the semiconductor substrate. The substrate grinding tool may press the grinding wheel against the semiconductor substrate using a mechanical downforce, and may rotate the grinding wheel while the grinding wheel is pressed against the semiconductor substrate to remove material from the semiconductor substrate.

In some cases, grinding a semiconductor substrate using the semiconductor grinding tool may result in surface damage (e.g., cracking) and/or increased roughness of the surface of the semiconductor substrate. This may increase current leakage in one or more semiconductor devices and/or semiconductor structures formed on the semiconductor substrate and/or may result in an increased likelihood of failure of one or more semiconductor devices formed on the semiconductor substrate.

In some implementations described herein, a substrate grinding tool is configured to remove material from a semiconductor substrate in a grinding operation. In the grinding operation, the substrate grinding tool uses a combination of mechanical grinding and a chemical etchant to remove material from the semiconductor substrate. The chemical etchant may be heated to a high temperature to increase the etch rate of the chemical etchant. The chemical etchant may include a silicon etchant such as potassium hydroxide (KOH) and/or another silicon etchant for which a silicon etch rate increases as the temperature of the silicon etchant increases.

In this way, the use of the combination of mechanical grinding and the chemical etchant may increase the grinding rate of the substrate grinding tool for grinding semiconductor substrates, which may increase the wafer per hour (WPH) processing throughput of the substrate grinding tool relative to the use of only mechanical grinding.

Moreover, the use of the combination of mechanical grinding and the chemical etchant may reduce surface damage and/or may reduce surface roughness for semiconductor substrates that are processed by the substrate grinding tool. This may reduce current leakage in one or more semiconductor devices formed on the semiconductor substrates and/or may reduce the likelihood of failure of one or more semiconductor devices formed on the semiconductor substrates, among other examples.

In addition, the reduced surface damage and/or reduced surface roughness for the semiconductor substrates may reduce the need for additional rework through additional chemical mechanical polishing (CMP) operations and/or additional etching operations. This may reduce the complexity of manufacturing semiconductor devices from the semiconductor substrates in that the quantity of processing steps may be reduced for manufacturing a semiconductor device, the amount of time for manufacturing the semiconductor device may be reduced, and/or the cost of manufacturing the semiconductor device may be reduced, among other examples.

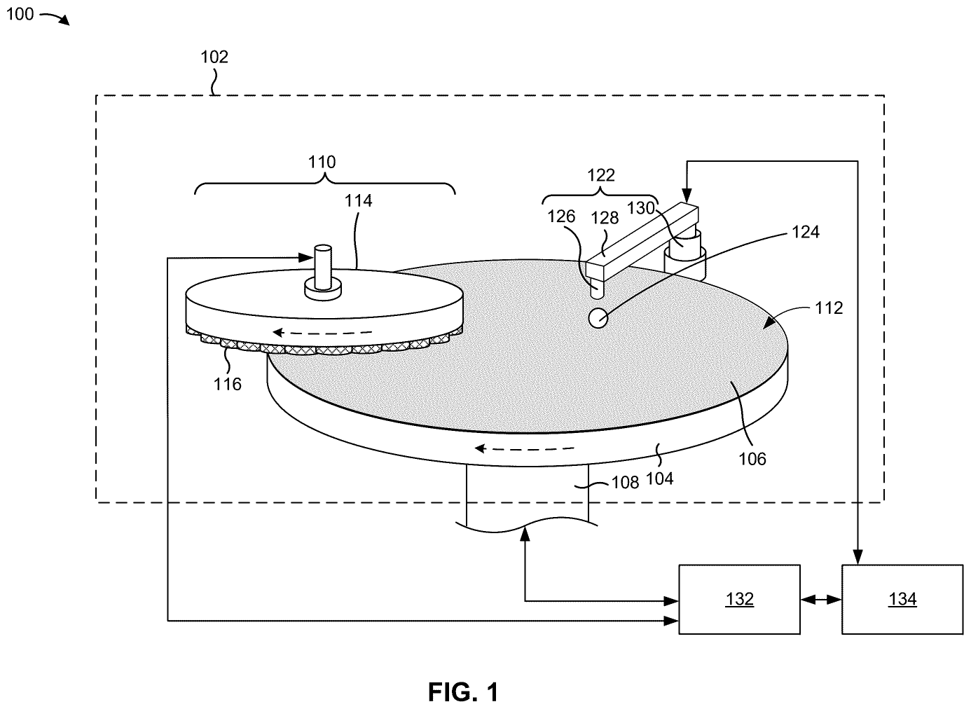

FIG. 1 is a diagram of a substrate grinding tool 100 described herein. The substrate grinding tool 100 includes a semiconductor processing tool that is configured to remove material from a semiconductor substrate using a combination of mechanical grinding and chemical etching (e.g., wet etching).

The substrate grinding tool 100 includes a processing chamber 102 in which semiconductor substrates may be processed. In some implementations, the processing chamber 102 may be sealed and/or climate controlled to enable precise control over one or more environmental parameters in the processing chamber. Examples of environmental parameters that may be controlled in the processing chamber 102 include temperature, humidity, oxygen concentration, and/or pressure, among other examples.

A platen 104 may be included in the processing chamber 102. The platen 104 may be configured to receive and support a semiconductor substrate 106 on the platen 104. The size and/or shape of the platen 104 may approximately conform to the semiconductor substrate 106. For example, the platen 104 may be approximately round and may be sized to receive and support a round semiconductor substrate 106.

In some implementations, the platen 104 may be configured to secure the semiconductor substrate 106 against the platen 104 to enable the platen 104 to rotate the semiconductor substrate 106. The platen 104 may be coupled with a drive shaft 108, which may drive the rotation of the platen 104. In some implementations, the platen 104 includes a chuck that is configured to secure the semiconductor substrate 106 to the platen 104. The chuck may include a vacuum chuck (e.g., a chuck that uses a vacuum force to bias the semiconductor substrate 106 against the platen 104), an electrostatic chuck (e.g., a chuck that uses an electrostatic force to bias the semiconductor substrate 106 against the platen 104), and/or another type of chuck. In some implementations, a wafer transport tool such as a robot arm may position the semiconductor substrate 106 on the platen 104.

The semiconductor substrate 106 may include semiconductor wafer, a stacked semiconductor wafer, or another type of semiconductor substrate. In some implementations, the semiconductor substrate 106 is formed of silicon (Si) (e.g., a silicon substrate), a material including silicon, a III-V compound semiconductor material such as gallium arsenide (GaAs), a silicon on insulator (SOI), or another type of semiconductor material. Alternatively, the semiconductor substrate 106 may include an insulator substrate and/or another type of substrate on which electronic devices may be formed.

A grinding assembly 110 may be at least partially included in the processing chamber 102 of the substrate grinding tool 100. The grinding assembly 110 may be configured to mechanically grind a surface 112 of the semiconductor substrate 106 to mechanically remove material from the semiconductor substrate 106. The grinding assembly 110 may include a grinding device 114 that includes an abrasive 116 configured to grind the surface 112 of the semiconductor substrate 106. The grinding device 114 may include a grinding disc, a grinding wheel, a grinding head, and/or another type of grinding device. The abrasive 116 may include one or more grinding elements, such as a sheet of a diamond abrasive, a plurality of diamond abrasive pads, and/or another type of abrasive. In some implementations, the abrasive 116 includes two or more diamond abrasive pads that have different grits (e.g., different roughness or coarseness) of diamond abrasive.

In some implementations, the grinding device 114 may be pivoted via an arm. The arm may be controlled through a shaft. The arm and/or the shaft of the grinding assembly 110 may be configured to rotate the grinding device 114. The grinding device 114 may be configured to rotate about an axis of the grinding device 114 (e.g., an axis that is approximately perpendicular to the surface 112 of the semiconductor substrate 106) in a grinding operation. In some implementations, the grinding device 114 is alternatively connected to spindle. However, other implementations of mounting the grinding device 114 are within the scope of the present disclosure.

To remove material from the semiconductor substrate 106, the grinding device 114 may be lowered onto the surface 112 of the semiconductor substrate 106 (e.g., by a shaft or a spindle) such that the abrasive 116 is in physical contact with the surface 112 of the semiconductor substrate 106. In some implementations, the grinding assembly 110 is configured to press the abrasive 116 of the grinding device 114 against the surface 112 of the semiconductor substrate 106 to apply a downforce against the surface 112 of the semiconductor substrate 106. The magnitude of the downforce, along with the rotational velocity of the grinding device 114 and/or the rotational velocity of the platen 104 may be selected to precisely control a material removal rate for removing material from the semiconductor substrate 106. The downforce (and/or the feed rate) of the grinding device 114, the rotational velocity of the grinding device 114, and/or the rotational velocity of the platen 104 may be selected based on a thickness of the semiconductor substrate 106, based on a grit of the abrasive 116, based on an amount of material to be removed from the semiconductor substrate 106, based on a material of the semiconductor substrate 106, and/or based on another parameter.

A dispensing system 122 may be at least partially included in the processing chamber 102 of the substrate grinding tool 100. The dispensing system 122 may be configured to dispense a chemical etchant 124 onto the surface 112 of the semiconductor substrate 106 while the semiconductor substrate 106 is positioned on the platen 104 in the processing chamber 102. In some implementations, the dispensing system 122 may be configured to dispense the chemical etchant 124 onto the surface 112 of the semiconductor substrate 106 during a grinding operation to remove material from the semiconductor substrate 106. The dispensing system 122 may include a dispenser nozzle 126 which can be pivoted via an arm 128. The arm 128 may be coupled to a shaft 130.

The chemical etchant 124 may be dispensed onto the surface 112 of the semiconductor substrate 106 so that the chemical etchant 124 etches the surface 112 of the semiconductor substrate 106. Etching the surface 112 (e.g., chemically etching the surface 112) of the semiconductor substrate 106 may reduce the surface roughness of the surface 112 of the semiconductor substrate 106. Mechanically grinding the surface 112 of the semiconductor substrate 106 using the grinding device 114 may coarsely remove material from the surface 112 of the semiconductor substrate 106, resulting in a rough surface on the semiconductor substrate 106. Chemically etching the surface 112 of the semiconductor substrate 106 may smooth out the surface 112 of the semiconductor substrate 106, thereby reducing the roughness of the surface 112 of the semiconductor substrate 106. In particular, the dispensing system 122 may dispense the chemical etchant 124 onto the surface 112 of the semiconductor substrate 106 while the platen 104 rotates the semiconductor substrate 106, where the rotation of the semiconductor substrate 106 causes the chemical etchant 124 to be dispersed across the surface 112 of the semiconductor substrate 106. The chemical etchant 124 may be dispensed at or near a center of the semiconductor substrate 106, and the rotation of the semiconductor substrate 106 may cause the chemical etchant 124 to flow radially outward from the center of the semiconductor substrate 106. This flow of the chemical etchant 124 may cause the chemical etchant 124 to chemically etch the peaks or high points of the surface 112, which reduces the surface roughness (e.g., the difference in height between the peaks and valleys) of the surface 112 of the semiconductor substrate 106.

In some implementations, the dispensing system 122 may be configured to dispense the chemical etchant 124 onto the surface 112 of the semiconductor substrate 106 to chemically etch the surface 112 of the semiconductor substrate 106 after the grinding device 114 mechanically removes material from the surface 112 of the semiconductor substrate 106. Chemically etching the surface 112 of the semiconductor substrate 106 after the grinding device 114 mechanically removes material from the surface 112 of the semiconductor substrate 106 may enable the substrate grinding tool 100 to performing a “finishing” process during a grinding operation to reduce a surface roughness of the surface 112 of the semiconductor substrate 106 after the grinding device 114 mechanically removes material from the surface 112 of the semiconductor substrate 106.

In some implementations, the dispensing system 122 may be configured to dispense the chemical etchant 124 onto the surface 112 of the semiconductor substrate 106 to chemically etch the surface 112 of the semiconductor substrate 106 while the grinding device 114 mechanically removes material from the surface 112 of the semiconductor substrate 106. The combination of mechanical grinding and chemical etching may increase the material removal rate of the substrate grinding tool 100 for removing material from the semiconductor substrate 106 while achieving a relatively low surface roughness for the surface 112 of the semiconductor substrate 106.

The chemical etchant 124 may include a chemical etchant that is capable of etching the material of the semiconductor substrate 106. For example, for a semiconductor substrate 106 that includes silicon (Si), the chemical etchant 124 may include a chemical etchant that is capable of etching silicon. Examples of chemical etchants 124 may include potassium hydroxide (KOH), sodium hydroxide (NaOH), another hydroxide, and/or another chemical etchant, among other examples. In some implementations, the chemical etchant 124 is selected to have a basic pH (e.g., a pH greater than water and/or greater than 7). In some implementations, the pH of the chemical etchant 124 is included in a range of approximately 10 to approximately 14 to achieve a sufficiently high etch rate for etching the semiconductor substrate 106 without unduly increasing manufacturing costs. However, other values for the range are within the scope of the present disclosure.

In some implementations, the chemical etchant 124 may include a solution in which a base chemical (e.g., KOH or NaOH, among other examples) is diluted in an aqueous solution that includes water (e.g., deionized water (DIW)). For example, approximately 5% to approximately 40% of a total volume of the solution may include the base chemical (e.g., the KOH or NaOH, among other examples) to achieve a sufficiently high etch rate for etching the semiconductor substrate 106 without unduly increasing manufacturing costs. However, other values for the range are within the scope of the present disclosure.

In some implementations, the dispensing system 122 may dispense the chemical etchant 124 onto the surface 112 of the semiconductor substrate 106 at an elevated temperature. The chemical etchant 124 may be heated prior to dispensing so that the chemical etchant 124 is dispensed at a high temperature onto the surface 112 of the semiconductor substrate 106. Dispensing the chemical etchant 124 onto the surface 112 of the semiconductor substrate 106 at a high temperature may increase the etch rate of the chemical etchant 124.

In some implementations, the dispensing system 122 may dispense the chemical etchant 124 onto the surface 112 at a temperature that satisfies a temperature threshold. For example, the dispensing system 122 may dispense the chemical etchant 124 onto the surface 112 at a temperature that greater than or approximately equal to 40 degrees Celsius to achieve a sufficiently high etch rate for etching the semiconductor substrate 106. However, other values are within the scope of the present disclosure. In some implementations, the dispensing system 122 may dispense the chemical etchant 124 onto the surface 112 at a temperature that is included in a particular temperature range such that an etch rate of the chemical etchant 124, for etching the surface 112 of the semiconductor substrate 106, satisfies an etch rate threshold. For example, the dispensing system 122 may dispense the chemical etchant 124 onto the surface 112 at a temperature that is included in a range of approximately 40 degrees Celsius to approximately 100 degrees Celsius such that an etch rate of the chemical etchant 124, for etching the surface 112 of the semiconductor substrate 106, satisfies an etch rate threshold. Moreover, dispensing the chemical etchant 124 at a temperature that is included in this range may reduce and/or minimize the likelihood of heat-related damage to the semiconductor substrate 106 and/or to semiconductor devices formed on the semiconductor substrate 106. However, other values for the range are within the scope of the present disclosure.

In this way, the substrate grinding tool 100 may include a processing chamber 102, a platen 104, in the processing chamber 102, configured to support a semiconductor substrate 106, a grinding device 114, in the processing chamber 102, that includes an abrasive 116 configured to mechanically remove material from the semiconductor substrate 106; and a dispenser nozzle 126, in the processing chamber 102, configured to dispense a chemical etchant 124 onto a surface 112 of the semiconductor substrate 106 to chemically etch the surface 112 of the semiconductor substrate 106. In some implementations, the dispenser nozzle 126 may be configured to dispense the chemical etchant 124 at a temperature that is included in a range of approximately 40 degrees Celsius to approximately 100 degrees Celsius. In some implementations, the dispenser nozzle 126 may be configured to dispense the chemical etchant 124 onto the surface 112 of the semiconductor substrate 106 while the platen 104 rotates the semiconductor substrate 106.

In some implementations, the dispenser nozzle 126 may be configured to dispense the chemical etchant 124 onto the surface 112 of the semiconductor substrate 106 while the grinding device 114 mechanically removes the material from the semiconductor substrate 106. In some implementations, the dispenser nozzle 126 may be configured to dispense the chemical etchant 124 onto the surface 112 of the semiconductor substrate 106 after the grinding device 114 mechanically removes the material from the semiconductor substrate 106. In some implementations, the dispenser nozzle 126 may be configured to dispense the chemical etchant 124 onto the surface 112 of the semiconductor substrate 106 while the grinding device 114 mechanically removes the material from the semiconductor substrate 106, and after the grinding device 114 mechanically removes the material from the semiconductor substrate 106.

As further shown in FIG. 1, the substrate grinding tool 100 may include a motor assembly 132 and a controller 134. The motor assembly 132 may be coupled with the grinding assembly 110 and/or with the drive shaft 108. The motor assembly 132 may include one or more motors, may be configured to raise and/or lower the grinding device 114, may be configured to articulate the grinding assembly 110, may be configured to rotate the grinding device 114, and/or may be configured to rotate the platen 104, among other examples.

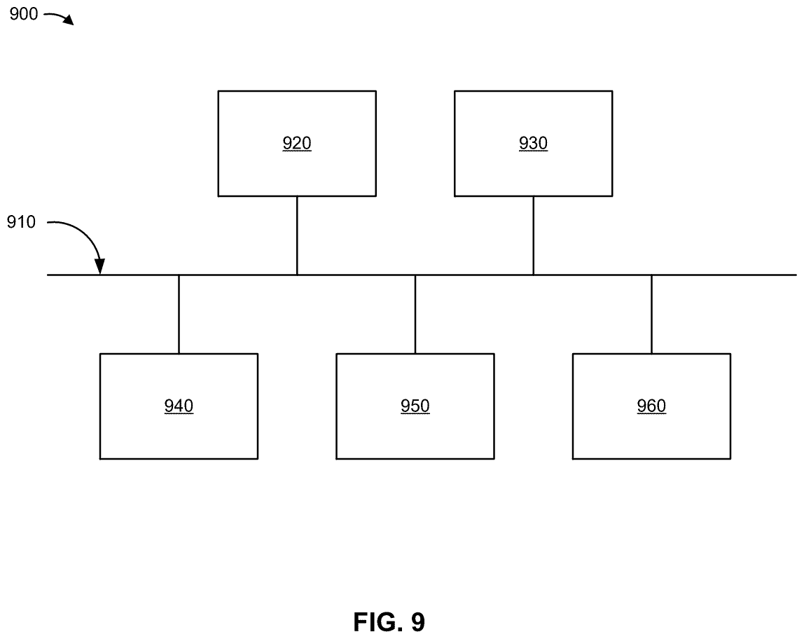

The controller 134 may be coupled with the motor assembly 132 and/or the dispensing system 122. The controller 134 may include a processor (e.g., a processor 920 described in connection with FIG. 9), a device (e.g., a device 900 described in connection with FIG. 9), and/or another type of hardware device. The controller 134 may be a processor configured to provide signals to and/or receive signals from the motor assembly 132 and/or the dispensing system 122. The signals may include electrical signals (e.g., a voltage, a current, a resistance, a capacitance), digital signals (e.g., a digital communication), and/or another type of signals. The controller 134 may provide one or more signals to the motor assembly 132 and/or the dispensing system 122 to control the operation of the substrate grinding tool 100. For example, the controller 134 may provide one or more signals to the motor assembly 132 and/or the dispensing system 122 to cause the substrate grinding tool 100 to perform a grinding operation. As another example, the controller 134 may provide one or more signals to the motor assembly 132 and/or the dispensing system 122 to modify one or more parameters of a grinding operation.

As indicated above, FIG. 1 is provided as an example. Other examples may differ from what is described with regard to FIG. 1.

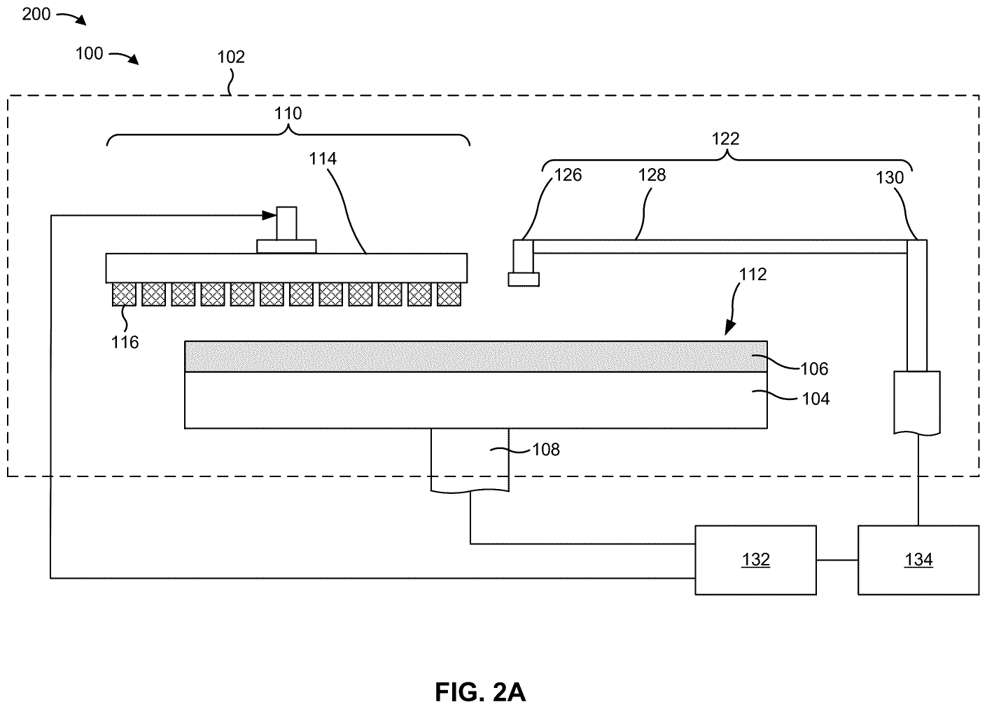

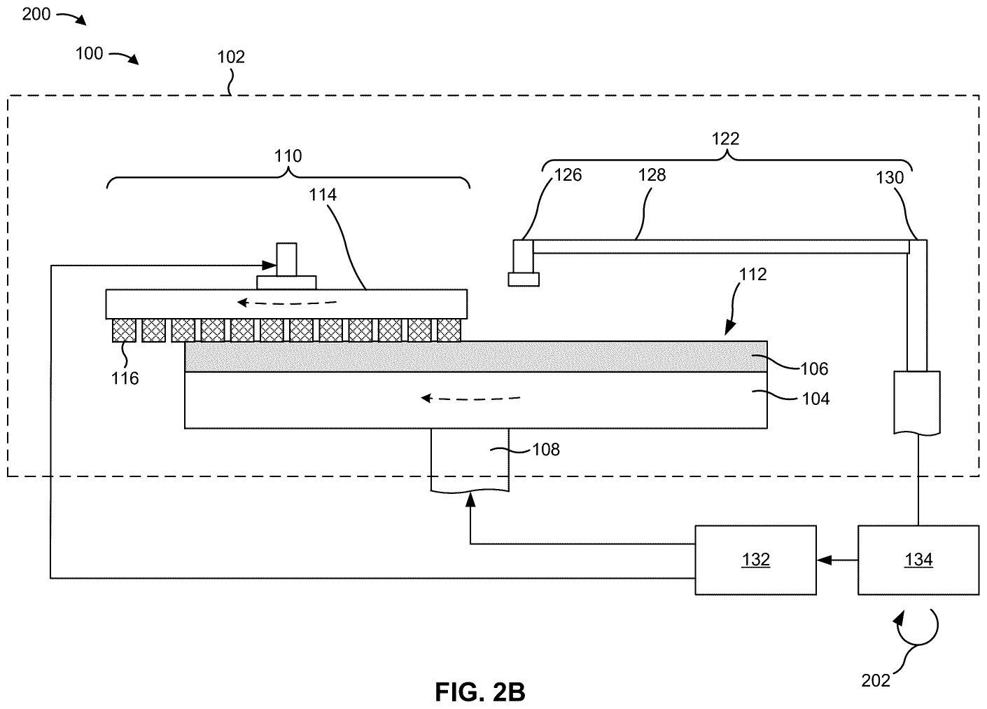

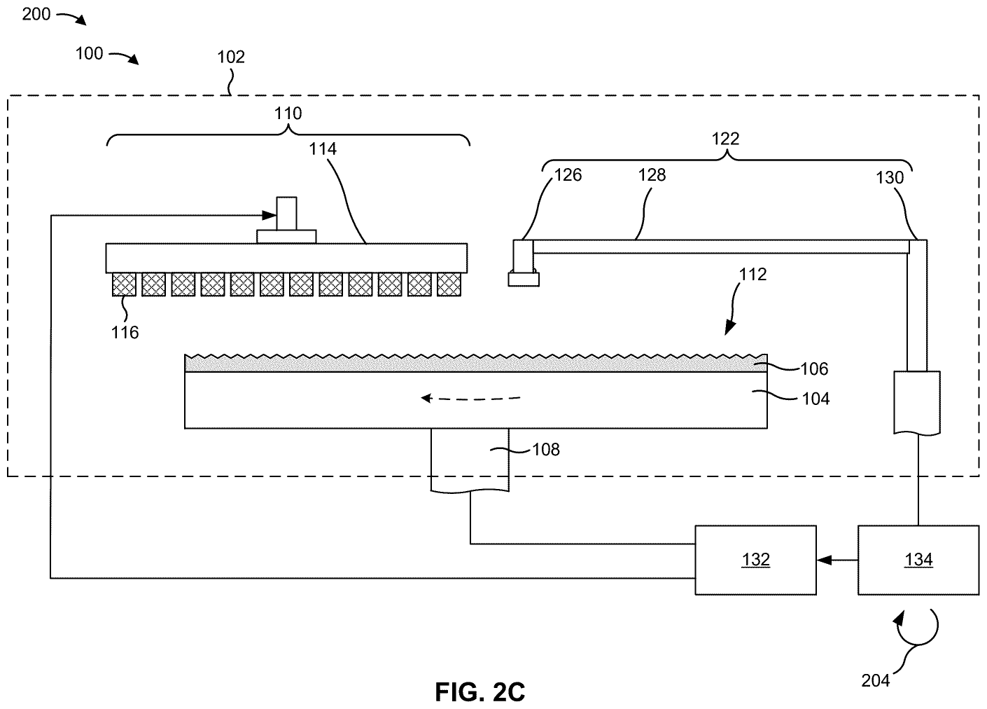

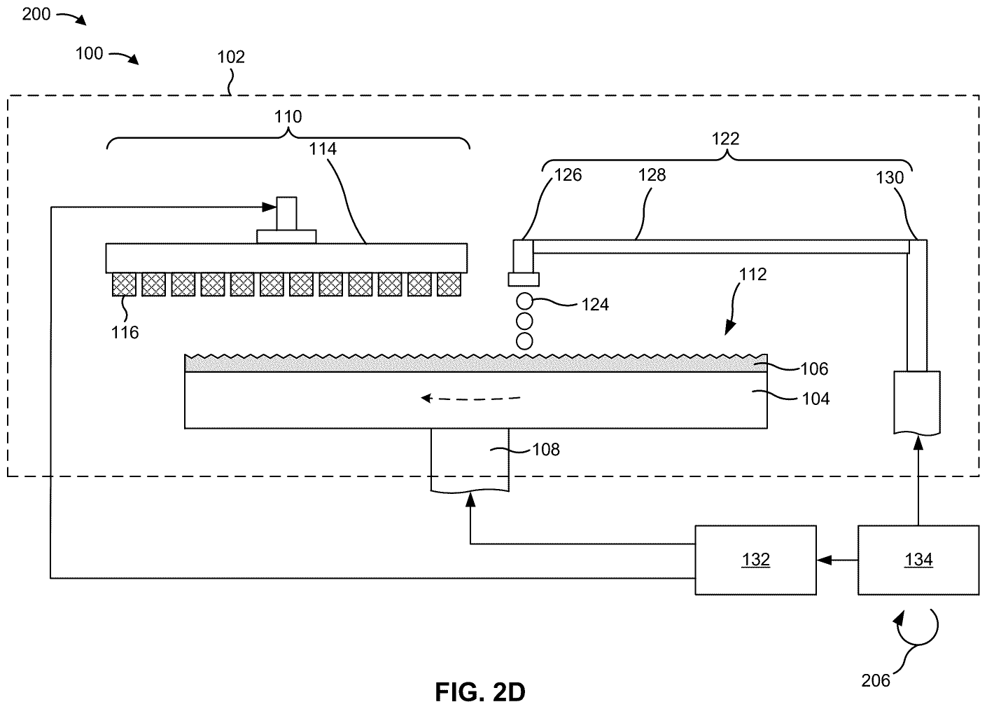

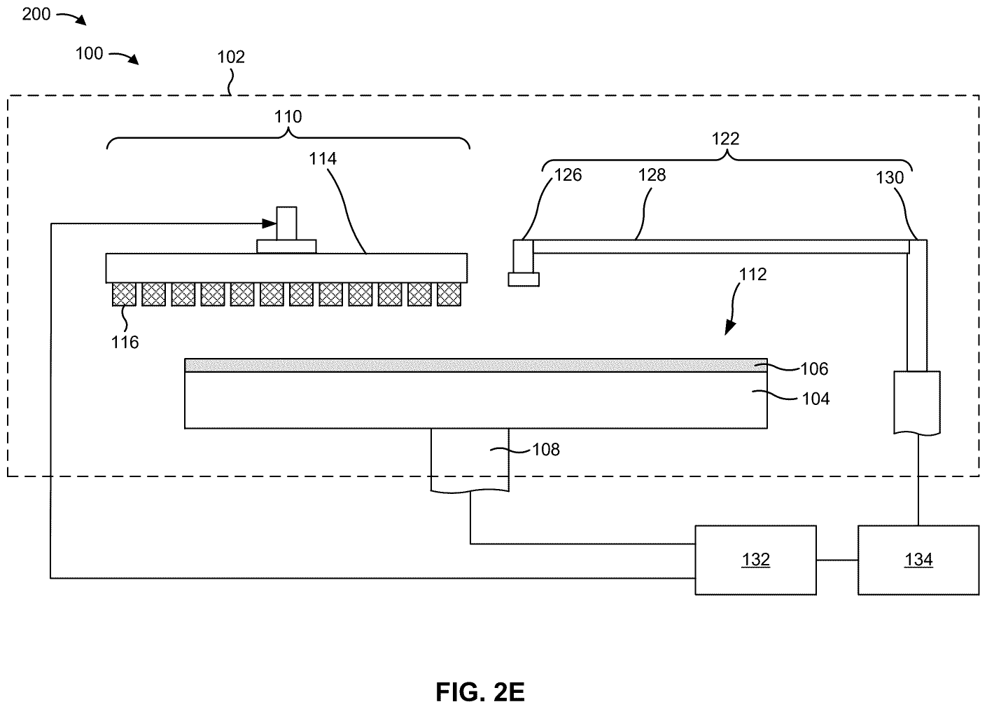

FIGS. 2A-2E are diagrams of an example implementation 200 of a grinding operation described herein. The grinding operation may be performed by the substrate grinding tool 100 to remove material from a semiconductor substrate 106. In some implementations, grinding operation may be performed to reduce a thickness of the semiconductor substrate 106. In some implementations, grinding operation may be performed on a backside of the semiconductor substrate 106 to remove material from the backside of the semiconductor substrate 106. In some implementations, grinding operation may be performed to prepare the semiconductor substrate 106 for bonding with another semiconductor substrate, for backside processing on the semiconductor substrate 106, and/or for additional processing.

As described in connection with FIGS. 2A-2E, the example implementation 200 may include positioning the semiconductor substrate 106 on the platen 104 in a processing chamber 102 of the substrate grinding tool 100 and performing, using the substrate grinding tool 100, a grinding operation to remove material from the semiconductor substrate 106 to reduce a thickness of the semiconductor substrate 106, where the chemical etchant 124 is dispensed onto a surface 112 of the semiconductor substrate 106 during the grinding operation to reduce a surface roughness of the surface 112 of the semiconductor substrate 106. The temperature of the chemical etchant 124 may be heated to satisfy a temperature threshold, which may increase the etch rate of the chemical etchant 124.

Turning to FIG. 2A, the semiconductor substrate 106 may be positioned in the processing chamber 102 on the platen 104. In some implementations, the semiconductor substrate 106 may be secured to the platen 104 by a chuck, which may include a vacuum chuck (e.g., a chuck that uses a vacuum force to bias the semiconductor substrate 106 against the platen 104), an electrostatic chuck (e.g., a chuck that uses an electrostatic force to bias the semiconductor substrate 106 against the platen 104), and/or another type of chuck. In some implementations, a wafer transport tool such as a robot arm may position the semiconductor substrate 106 on the platen 104.

As shown in FIG. 2B, the substrate grinding tool 100 may perform a grinding operation to remove material from the semiconductor substrate 106. At 202, the controller 134 may provide one or more signals to the motor assembly 132 to cause the motor assembly 132 to retract the shaft 120, which may cause the shaft 120 to lower the grinding device 114. The grinding device 114 may be lowered such that the abrasive 116 physically contacts the surface 112 of the semiconductor substrate 106. The one or more signals may include an electrical signal such as a voltage, a current, and/or another type of electrical signal. In some implementations, the one or more signals may include a digital signal such as a digital communication.

As further shown in FIG. 2B, the one or more signals may cause the motor assembly 132 to rotate the grinding device 114 against the surface 112 of the semiconductor substrate 106. Additionally, or alternatively, the controller 134 may provide one or more signals to the motor assembly 132 to cause the motor assembly 132 to rotate the platen 104, which rotates the semiconductor substrate 106 on the platen 104.

Pressing the abrasive 116 against the surface 112 of the semiconductor substrate 106 while the grinding device 114 and the semiconductor substrate 106 are rotated causes the abrasive 116 to grind against the surface 112 of the semiconductor substrate 106. This causes the abrasive 116 to mechanically grind the surface 112 of the semiconductor substrate 106 to remove material from the surface 112 of the semiconductor substrate 106. The grinding device 114 may mechanically grind the surface 112 of the semiconductor substrate 106 during a first part of the grinding operation to remove material from the semiconductor substrate 106 (e.g., to reduce a thickness of the semiconductor substrate 106).

As shown in FIG. 2C, at 204, the controller 134 may provide one or more signals to the motor assembly 132, which may cause the motor assembly 132 to cease rotation of the griding device 114 and to raise the grinding device 114 off of the surface 112 of the semiconductor substrate 106. This stops the mechanical grinding of the semiconductor substrate 106 during the first part of the grinding operation. In some implementations, the substrate grinding tool 100 may stop the mechanical grinding of the semiconductor substrate 106 based on achieving a threshold thickness for the semiconductor substrate 106 and/or based on expiration of a particular time period, among other examples.

As further shown in FIG. 2C, the mechanical grinding of the semiconductor substrate 106 may result in increased surface roughness for the surface 112 of the semiconductor substrate 106. The mechanical grinding of the semiconductor substrate 106 may coarsely grind the semiconductor substrate 106 to achieve a high rate of material removal from the semiconductor substrate 106, which may result in the increased surface roughness for the surface 112 of the semiconductor substrate 106.

As shown in FIG. 2D, at 206, the controller 134 may provide one or more signals to the dispensing system 122 to cause the dispensing system 122 to dispense a chemical etchant 124 (e.g., potassium hydroxide (KOH), sodium hydroxide (NaOH)) onto the surface 112 of the semiconductor substrate 106 through the dispenser nozzle 126. The chemical etchant 124 may be dispensed onto the surface 112 of the semiconductor substrate 106 in a second part of the grinding operation in which the chemical etchant 124 chemically etches the surface 112 of the semiconductor substrate 106 to reduce the surface roughness of the surface 112 of the semiconductor substrate 106. The substrate grinding tool 100 may perform the second part of the grinding operation after performing the first part of the grinding operation.

The chemical etchant 124 may be heated and dispensed through the dispenser nozzle 126 at a high temperature (e.g., to increase the etch rate of the chemical etchant 124). The semiconductor substrate 106 may be rotated on the platen 104 while the chemical etchant 124 is dispensed onto the surface 112 of the semiconductor substrate 106, which causes the chemical etchant 124 to be dispersed across the surface 112 of the semiconductor substrate 106.

As shown in FIG. 2E, the chemical etchant 124 chemically etches the surface 112 of the semiconductor substrate 106, which reduces the surface roughness of the surface 112 of the semiconductor substrate 106. The controller 134 may provide one or more signals to the dispensing system 122 to stop the dispensing of the chemical etchant 124. Additionally, or alternatively, the controller 134 may provide one or more signals to the motor assembly 132 to cause the motor assembly 132 to stop the rotation of the semiconductor substrate 106.

In this way, the example implementation 200 may include positioning the semiconductor substrate 106 on the platen 104 in the processing chamber 102 of the substrate grinding tool 100. The example implementation 200 may include performing, using the grinding device 114 of the substrate grinding tool 100, a first part of a grinding operation to remove material from the semiconductor substrate 106. The example implementation 200 may include performing, using the chemical etchant 124 dispensed onto the surface 112 of the semiconductor substrate 106 in the processing chamber 102, a second part of the grinding operation after the first part of the grinding operation. The chemical etchant 124 may be dispensed onto the surface 112 of the semiconductor substrate 106 at a temperature that is included in a particular temperature range such that an etch rate of the chemical etchant 124, for etching the surface 112 of the semiconductor substrate 106, satisfies an etch rate threshold.

As indicated above, FIGS. 2A-2E are provided as an example. Other examples may differ from what is described with regard to FIGS. 2A-2E.

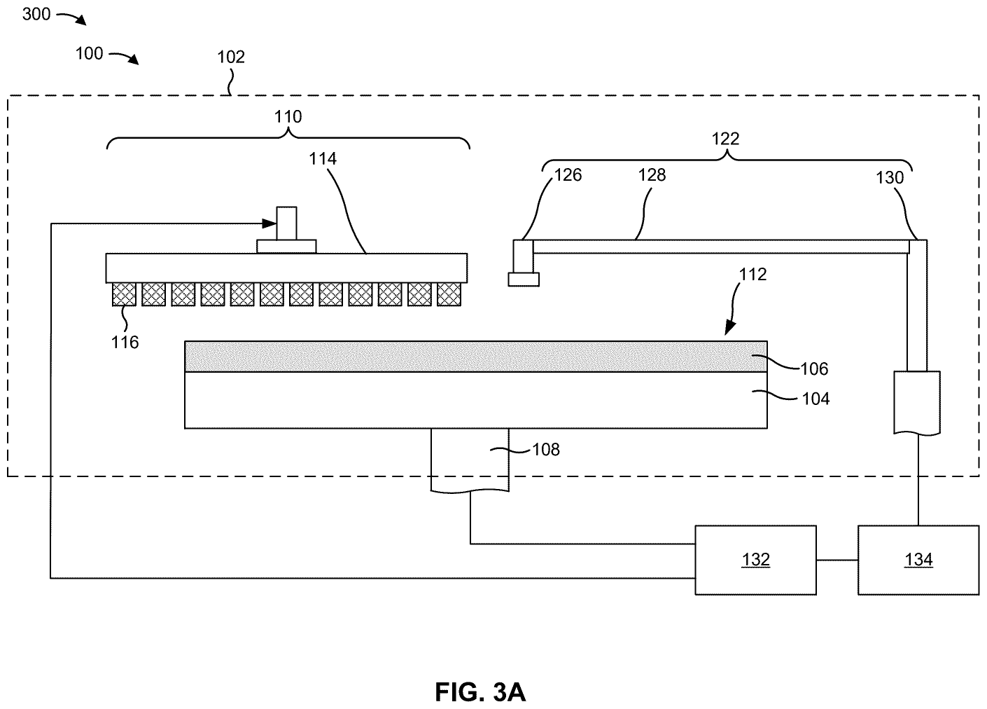

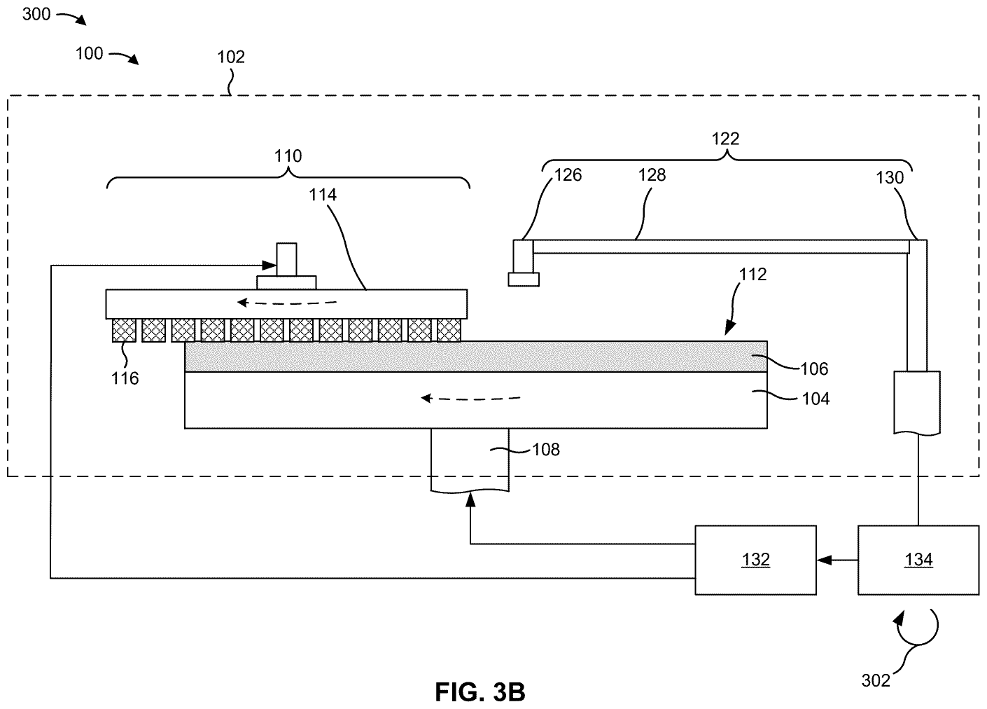

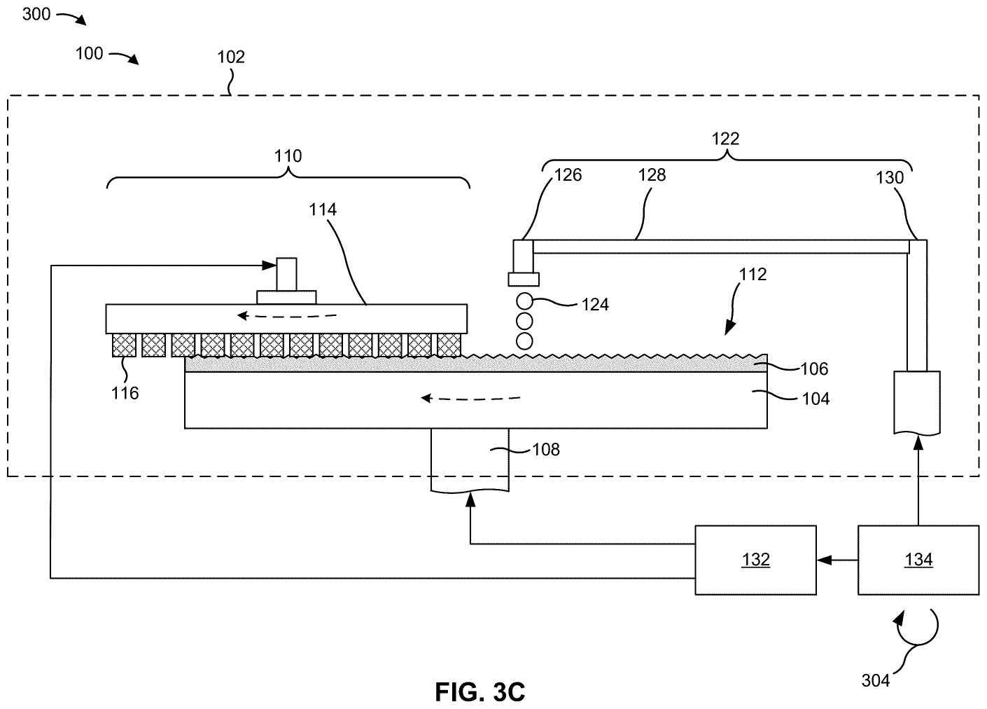

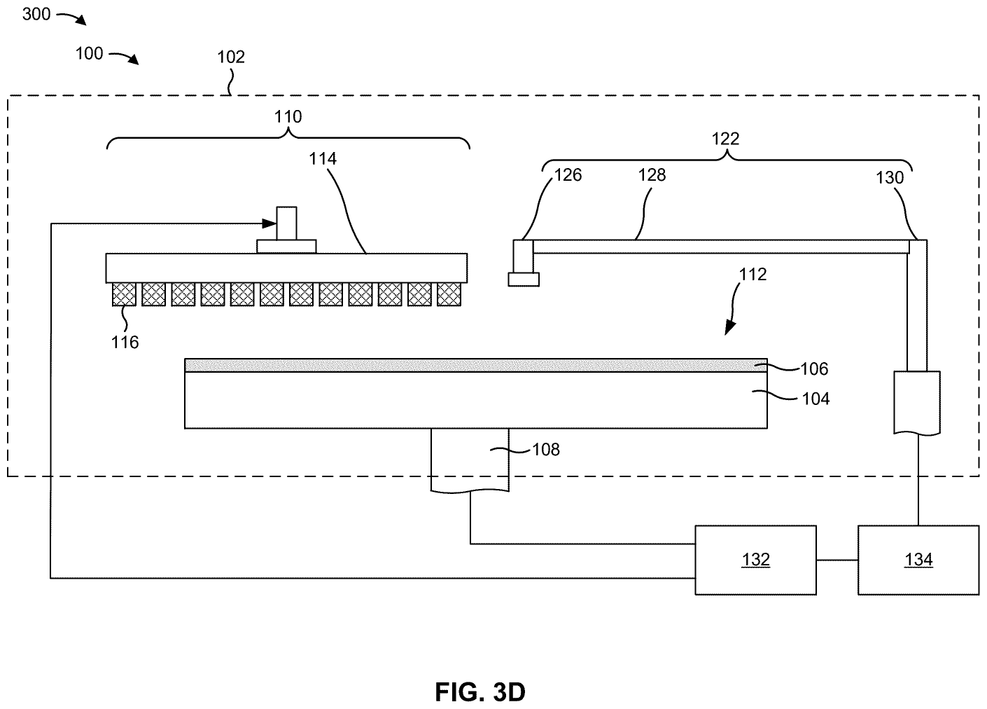

FIGS. 3A-3D are diagrams of an example implementation 300 of a grinding operation described herein. The grinding operation may be performed by the substrate grinding tool 100 to remove material from a semiconductor substrate 106. The example implementation 300 differs from the example implementation 200 in that, after an initial grinding period, the chemical etchant 124 is dispensed onto a surface 112 of the semiconductor substrate 106 while the grinding device 114 continues to grind the surface of the semiconductor substrate. In some implementations, grinding operation may be performed to reduce a thickness of the semiconductor substrate 106. In some implementations, grinding operation may be performed on a backside of the semiconductor substrate 106 to remove material from the backside of the semiconductor substrate 106. In some implementations, grinding operation may be performed to prepare the semiconductor substrate 106 for bonding with another semiconductor substrate, for backside processing on the semiconductor substrate 106, and/or for additional processing.

As described in connection with FIGS. 3A-3D, the example implementation 300 may include positioning the semiconductor substrate 106 on the platen 104 in the processing chamber 102 of the substrate grinding tool 100. The example implementation 300 may include performing, using the grinding device 114 only (e.g., no chemical etchant), a first part of a grinding operation to remove material from the semiconductor substrate 106. The example implementation 300 may include performing a second part of the grinding operation after the first part of the grinding operation. In the second part of the grinding operation, a combination of mechanical grinding using the grinding device 114 and chemical etching using the chemical etchant 124 may be performed. The chemical etchant 124 may be dispensed onto the surface 112 of the semiconductor substrate 106 at a temperature that is included in a particular temperature range such that an etch rate of the chemical etchant 124, for etching the surface 112 of the semiconductor substrate 106, satisfies an etch rate threshold.

Turning to FIG. 3A, the semiconductor substrate 106 may be positioned in the processing chamber 102 on the platen 104. In some implementations, the semiconductor substrate 106 may be secured to the platen 104 by a chuck, which may include a vacuum chuck (e.g., a chuck that uses a vacuum force to bias the semiconductor substrate 106 against the platen 104), an electrostatic chuck (e.g., a chuck that uses an electrostatic force to bias the semiconductor substrate 106 against the platen 104), and/or another type of chuck. In some implementations, a wafer transport tool such as a robot arm may position the semiconductor substrate 106 on the platen 104.

As shown in FIG. 3B, the substrate grinding tool 100 may perform a grinding operation to remove material from the semiconductor substrate 106. At 302, the controller 134 may provide one or more signals to the motor assembly 132 to cause the motor assembly 132 to retract the shaft 120, which may cause the shaft 120 to lower the grinding device 114. The grinding device 114 may be lowered such that the abrasive 116 physically contacts the surface 112 of the semiconductor substrate 106. The one or more signals may include an electrical signal such as a voltage, a current, and/or another type of electrical signal. In some implementations, the one or more signals may include a digital signal such as a digital communication.

As further shown in FIG. 3B, the one or more signals may cause the motor assembly 132 to rotate the grinding device 114 against the surface 112 of the semiconductor substrate 106. Moreover, the controller 134 may provide one or more signals to the motor assembly 132 to cause the motor assembly 132 to rotate the platen 104, which rotates the semiconductor substrate 106 on the platen 104.

Pressing the abrasive 116 against the surface 112 of the semiconductor substrate 106 while the grinding device 114 and the semiconductor substrate 106 are rotated causes the abrasive 116 to grind against the surface 112 of the semiconductor substrate 106. This causes the abrasive 116 to mechanically grind the surface 112 of the semiconductor substrate 106 to remove material from the surface 112 of the semiconductor substrate 106. The grinding device 114 may mechanically grind the surface 112 of the semiconductor substrate 106 during a first part of the grinding operation to remove material from the semiconductor substrate 106 (e.g., to reduce a thickness of the semiconductor substrate 106).

As shown in FIG. 3C, at 304, a second part of the grinding operation may be performed after the first part of the grinding operation. In the second part of the grinding operation, the controller 134 may provide one or more signals to the dispensing system 122 to cause the dispensing system 122 to dispense a chemical etchant 124 (e.g., potassium hydroxide (KOH), sodium hydroxide (NaOH)) onto the surface 112 of the semiconductor substrate 106 through the dispenser nozzle 126. The chemical etchant 124 may be dispensed onto the surface 112 of the semiconductor substrate 106. The chemical etchant 124 chemically etches the surface 112 of the semiconductor substrate 106 to reduce the surface roughness of the surface 112 of the semiconductor substrate 106 while the grinding device 114 grinds the surface 112 of the semiconductor substrate 106.

The chemical etchant 124 may be heated and dispensed through the dispenser nozzle 126 at a high temperature (e.g., to increase the etch rate of the chemical etchant 124). The semiconductor substrate 106 may be rotated on the platen 104 while the chemical etchant 124 is dispensed onto the surface 112 of the semiconductor substrate 106, which causes the chemical etchant 124 to be dispersed across the surface 112 of the semiconductor substrate 106.

As shown in FIG. 3D, the chemical etchant 124 chemically etches the surface 112 of the semiconductor substrate 106, which reduces the surface roughness of the surface 112 of the semiconductor substrate 106. The controller 134 may provide one or more signals to the dispensing system 122 to stop the dispensing of the chemical etchant 124. Moreover, the controller 134 may provide one or more signals to the motor assembly 132 to cause the motor assembly 132 to stop the rotation of the semiconductor substrate 106. Additionally, the controller 134 may provide one or more signals to the motor assembly 132 to cause the motor assembly 132 to stop the rotation of the grinding device 114 and to raise the grinding device 114 off of the surface 112 of the semiconductor substrate 106.

In some implementations, the controller 134 may determine a time for transitioning from the first part of the grinding operation (in which only mechanical grinding is performed) to the second part of the grinding operation (in which the combination of mechanical grinding and chemical etching is performed). In some implementations, the controller 134 may determine to transition from the first part of the grinding operation to the second part of the grinding operation based on achieving threshold thickness for the semiconductor substrate 106 in the first part of the grinding operation.

In some implementations, the controller 134 may determine to transition from the first part of the grinding operation to the second part of the grinding operation using a machine learning model. In some implementations, the controller 134 uses the machine learning model to determine the time for transitioning from the first part of the grinding operation to the second part of the grinding operation by providing candidate times or candidate thicknesses of the semiconductor substrate 106 as input to the machine learning model, and using the machine learning model to determine a likelihood, probability, or confidence that a particular outcome will be achieved (e.g., a threshold surface roughness for the surface 112 is achieved, a final thickness for the semiconductor substrate 106 is achieved) using the candidate parameters. In some implementations, the controller 134 provides a threshold surface roughness for the surface 112 and/or a final thickness for the semiconductor substrate 106 as input to the machine learning model, and the controller 134 uses the machine learning model to determine or identify a candidate time for transitioning from the first part of the grinding operation to the second part of the grinding operation that is likely to achieve the threshold surface roughness for the surface 112 and/or the final thickness for the semiconductor substrate 106. In some implementations, the controller 134 uses the machine learning model to determine or identify a type of etchant, a temperature for the etchant, and/or another parameter for the grinding operation. Additional inputs to the machine learning model that the controller 134 may use may include material of the semiconductor substrate 106, a type and/or a grit of the abrasive 116, and/or another parameter.

The controller 134 (or another system) may train, update, and/or refine the machine learning model to increase the accuracy of the outcomes and/or parameters determined using the machine learning model. The controller 134 may train, update, and/or refine the machine learning model based on feedback and/or results from the grinding operation, as well as from historical or related grinding operations (e.g., from hundreds, thousands, or more historical or related grinding operations) performed by the substrate grinding tool 100.

In some implementations, the controller 134 may use similar machine learning techniques in the example implementation 200 described above in connection with FIGS. 2A-2E.

As indicated above, FIGS. 3A-3D are provided as an example. Other examples may differ from what is described with regard to FIGS. 3A-3D.

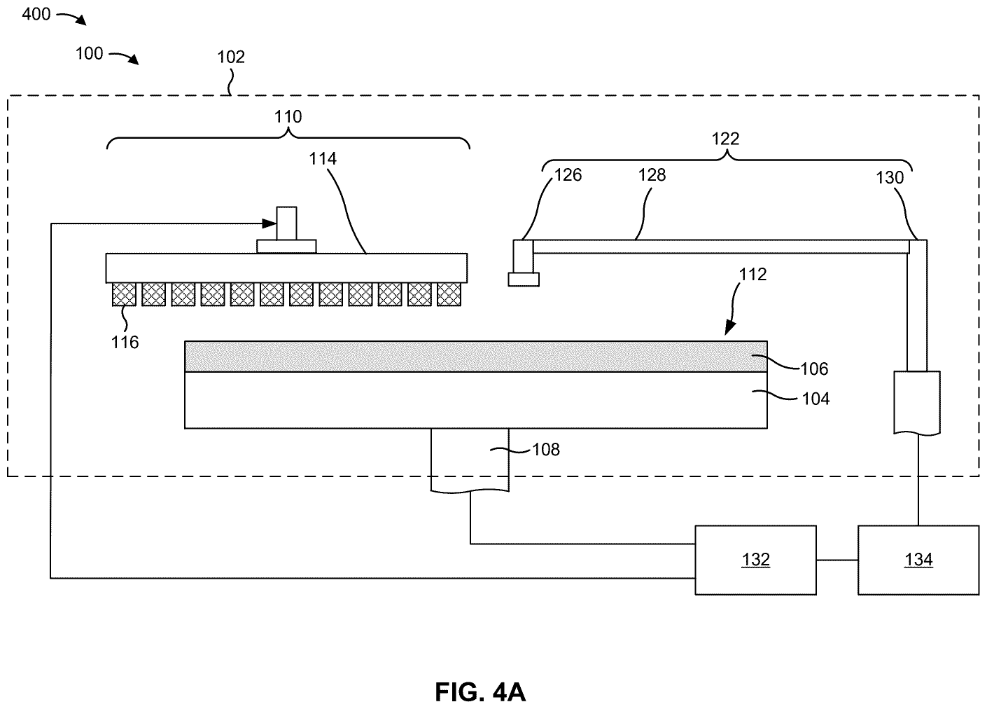

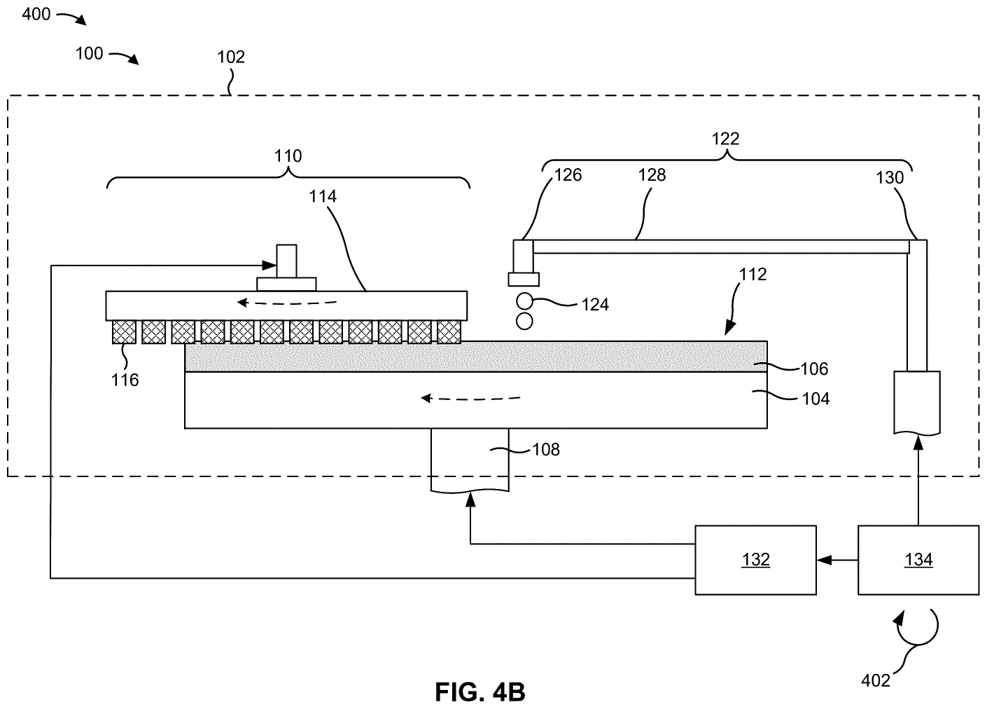

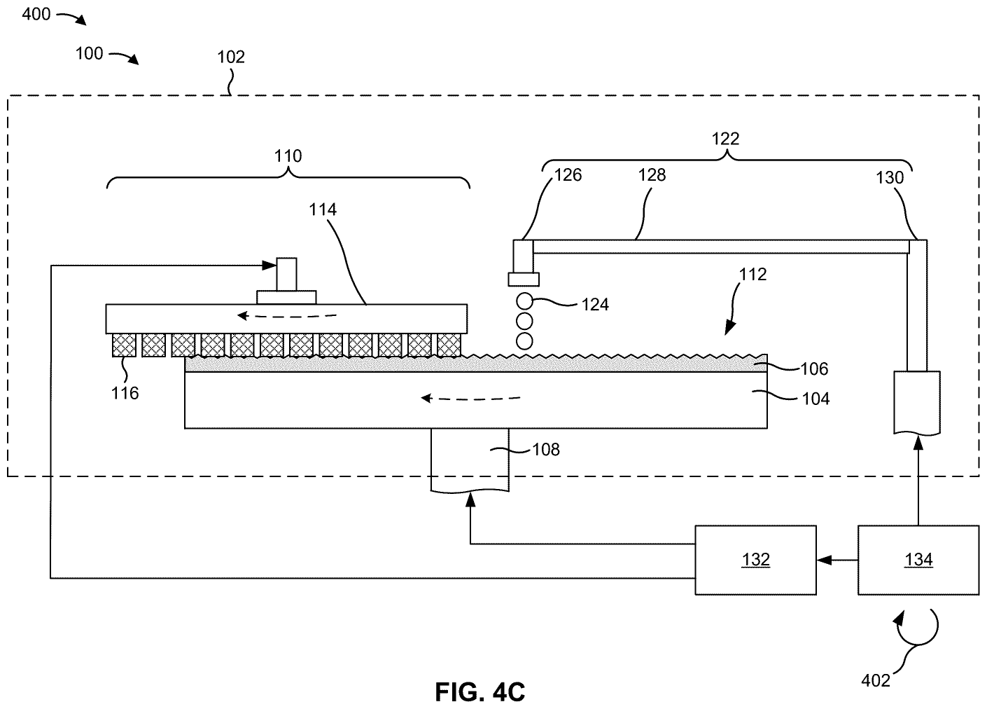

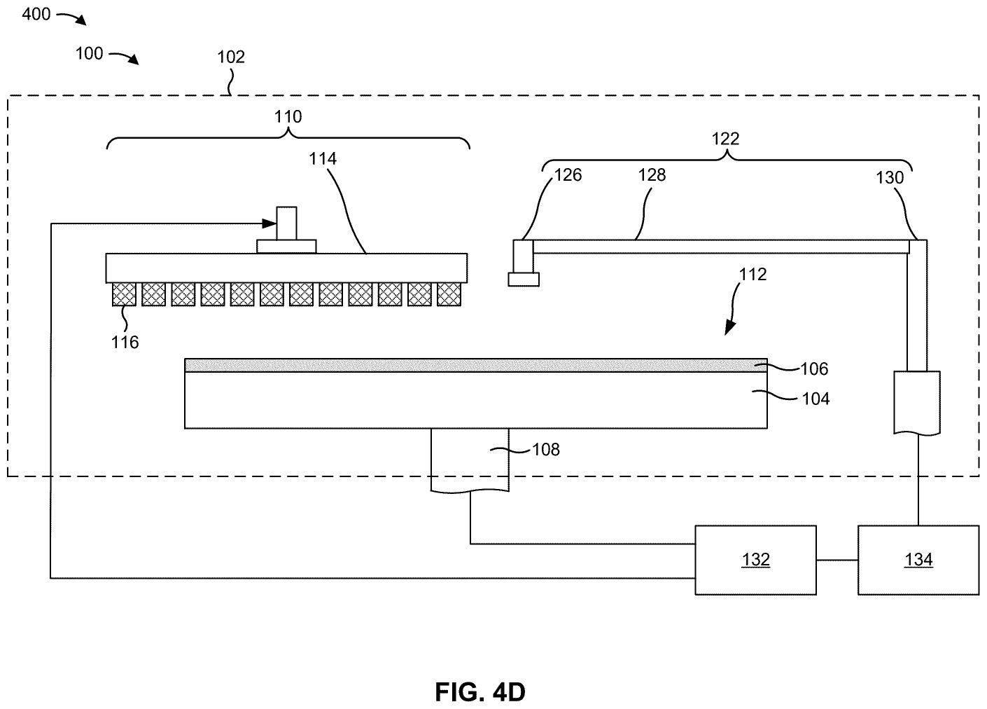

FIGS. 4A-4D are diagrams of an example implementation 400 of a grinding operation described herein. The grinding operation may be performed by the substrate grinding tool 100 to remove material from a semiconductor substrate 106. The example implementation 400 differs from the example implementation 200 and 300 in that the chemical etchant 124 is dispensed onto a surface 112 of the semiconductor substrate 106 at the beginning of the grinding operation while the grinding device 114 grinds the surface of the semiconductor substrate throughout the grinding operation. In some implementations, grinding operation may be performed to reduce a thickness of the semiconductor substrate 106. In some implementations, grinding operation may be performed on a backside of the semiconductor substrate 106 to remove material from the backside of the semiconductor substrate 106. In some implementations, grinding operation may be performed to prepare the semiconductor substrate 106 for bonding with another semiconductor substrate, for backside processing on the semiconductor substrate 106, and/or for additional processing.

As described in connection with FIGS. 4A-4D, the example implementation 400 may include positioning the semiconductor substrate 106 on the platen 104 in the processing chamber 102 of the substrate grinding tool 100. The example implementation 400 may include performing a grinding operation using a combination of mechanical grinding using the grinding device 114 and chemical etching using the chemical etchant 124. The chemical etchant 124 may be dispensed onto the surface 112 of the semiconductor substrate 106 at a temperature that is included in a particular temperature range such that an etch rate of the chemical etchant 124, for etching the surface 112 of the semiconductor substrate 106, satisfies an etch rate threshold.

Turning to FIG. 4A, the semiconductor substrate 106 may be positioned in the processing chamber 102 on the platen 104. In some implementations, the semiconductor substrate 106 may be secured to the platen 104 by a chuck, which may include a vacuum chuck (e.g., a chuck that uses a vacuum force to bias the semiconductor substrate 106 against the platen 104), an electrostatic chuck (e.g., a chuck that uses an electrostatic force to bias the semiconductor substrate 106 against the platen 104), and/or another type of chuck. In some implementations, a wafer transport tool such as a robot arm may position the semiconductor substrate 106 on the platen 104.

As shown in FIGS. 4B and 4C, the substrate grinding tool 100 may perform a grinding operation to remove material from the semiconductor substrate 106. At 402, the controller 134 may provide one or more signals to the motor assembly 132 to cause the motor assembly 132 to retract the shaft 120, which may cause the shaft 120 to lower the grinding device 114. The grinding device 114 may be lowered such that the abrasive 116 physically contacts the surface 112 of the semiconductor substrate 106. The one or more signals may include an electrical signal such as a voltage, a current, and/or another type of electrical signal. In some implementations, the one or more signals may include a digital signal such as a digital communication.

As further shown in FIGS. 4B and 4C, the one or more signals may cause the motor assembly 132 to rotate the grinding device 114 against the surface 112 of the semiconductor substrate 106. Additionally, or alternatively, the controller 134 may provide one or more signals to the motor assembly 132 to cause the motor assembly 132 to rotate the platen 104, which rotates the semiconductor substrate 106 on the platen 104.

Pressing the abrasive 116 against the surface 112 of the semiconductor substrate 106 while the grinding device 114 and the semiconductor substrate 106 are rotated causes the abrasive 116 to grind against the surface 112 of the semiconductor substrate 106. This causes the abrasive 116 to mechanically grind the surface 112 of the semiconductor substrate 106 to remove material from the surface 112 of the semiconductor substrate 106.

As further shown in FIGS. 4B and 4C, the controller 134 may additionally provide one or more signals to the dispensing system 122 to cause the dispensing system 122 to dispense a chemical etchant 124 (e.g., potassium hydroxide (KOH), sodium hydroxide (NaOH)) onto the surface 112 of the semiconductor substrate 106 through the dispenser nozzle 126 during the grinding operation. The chemical etchant 124 may be dispensed onto the surface 112 of the semiconductor substrate 106. The chemical etchant 124 chemically etches the surface 112 of the semiconductor substrate 106 to reduce the surface roughness of the surface 112 of the semiconductor substrate 106 while the grinding device 114 grinds the surface 112 of the semiconductor substrate 106.

The chemical etchant 124 may be heated and dispensed through the dispenser nozzle 126 at a high temperature (e.g., to increase the etch rate of the chemical etchant 124). The semiconductor substrate 106 may be rotated on the platen 104 while the chemical etchant 124 is dispensed onto the surface 112 of the semiconductor substrate 106, which causes the chemical etchant 124 to be dispersed across the surface 112 of the semiconductor substrate 106.

As shown in FIG. 4D, the chemical etchant 124 chemically etches the surface 112 of the semiconductor substrate 106, which reduces the surface roughness of the surface 112 of the semiconductor substrate 106. The controller 134 may provide one or more signals to the dispensing system 122 to stop the dispensing of the chemical etchant 124. Moreover, the controller 134 may provide one or more signals to the motor assembly 132 to cause the motor assembly 132 to stop the rotation of the semiconductor substrate 106. Additionally, the controller 134 may provide one or more signals to the motor assembly 132 to cause the motor assembly 132 to stop the rotation of the grinding device 114 and to raise the grinding device 114 off of the surface 112 of the semiconductor substrate 106.

As indicated above, FIGS. 4A-4D are provided as an example. Other examples may differ from what is described with regard to FIGS. 4A-4D.

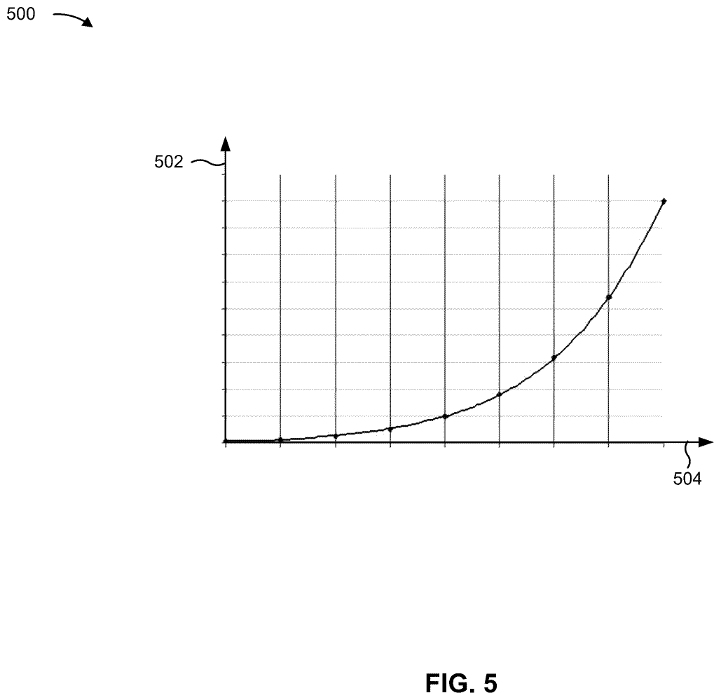

FIG. 5 is a diagram of an example implementation 500 of an etch rate 502 of a chemical etchant 124 for use in the substrate grinding tool described herein. The etch rate 502 is illustrated as a function of temperature 504 of the chemical etchant 124. The etch rate 502 may be illustrated for an example chemical etchant 124 that includes a solution in which potassium hydroxide (KOH) is diluted in deionized water to approximately 30% of the total volume of the solution, and for an example semiconductor substrate 106 that includes silicon (Si) having a (100) grain orientation.

As shown in FIG. 5, the etch rate 502 of the chemical etchant 124 generally increases as the temperature 504 of the chemical etchant 124 increases. In particular, the etch rate 502 of the chemical etchant 124 may approximately exponentially increase as the temperature 504 of the chemical etchant 124 increases.

As described herein, the chemical etchant 124 may be dispensed onto a semiconductor substrate 106 at a temperature 504 that is included in a temperature range to achieve a particular etch rate 502. For example, the chemical etchant 124 may be dispensed onto a semiconductor substrate 106 at a temperature 504 that is included in a range of approximately 40 degrees Celsius to approximately 100 degrees Celsius to achieve an etch rate 502 that is included in a range of approximately 10 microns per hour to approximately 225 microns per hour. However, other values for the ranges are within the scope of the present disclosure.

As indicated above, FIG. 5 is provided as an example. Other examples may differ from what is described with regard to FIG. 5.

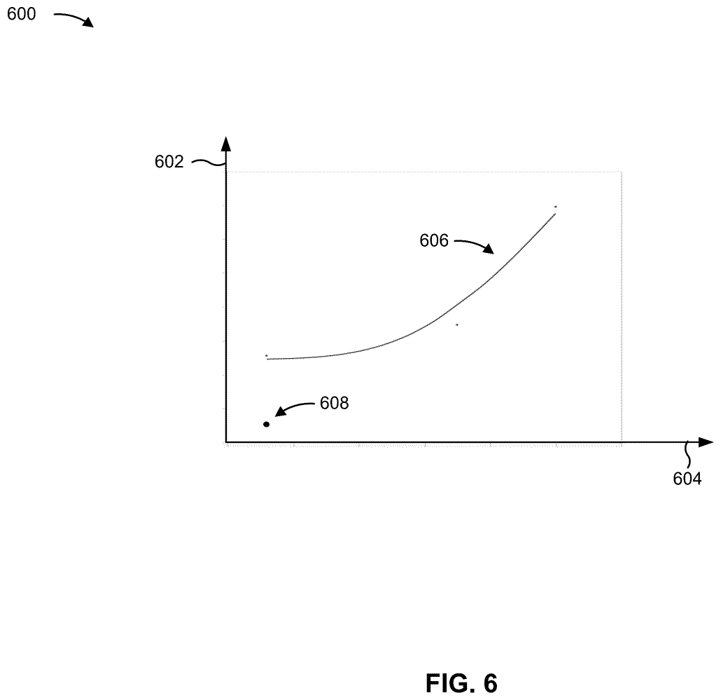

FIG. 6 is a diagram of an example implementation 600 of a grind rate 602 of the substrate grinding tool 100 described herein. The grind rate 602 may correspond to rate of removal of material from a semiconductor substrate 106, in an example grinding operation performed by the substrate grinding tool 100, in which the grinding device 114 mechanically grinds the semiconductor substrate 106 while a chemical etchant 124 is dispensed onto the semiconductor substrate 106. In the example grinding operation, the chemical flow rate of the chemical etchant 124 may be approximately 500 milliliters per minute, the rotational velocity of the platen 104 may be approximately 60 revolutions per minute, and/or the pressure in the processing chamber 102 may be approximately 0.2 bar. However, other values are within the scope of the present disclosure.

The grind rate 602 is illustrated as a function of temperature 604 of a plurality of example chemical etchants 124. The grind rate 602 may be illustrated for an example chemical etchant 124 that includes a solution in which potassium hydroxide (KOH) is diluted in deionized water to approximately 30% of the total volume of the solution (corresponding to plot line 606 in FIG. 6).

As shown in FIG. 6, the grind rate 602 generally increases in the grinding operation through the use of the example chemical etchants 124 (corresponding to plot line 606) relative to the use of deionized water (corresponding to data point 608 in FIG. 6). Moreover, the grind rate 602 generally increases as the temperature 604 of the example chemical etchants 124 increase.

As described herein, the chemical etchant 124 may be dispensed onto a semiconductor substrate 106 at a temperature 604 that is included in a temperature range to achieve a particular grind rate 602. For example, a KOH chemical etchant (corresponding to plot line 606) may be dispensed onto a semiconductor substrate 106 at a temperature 604 that is included in a range of approximately 40 degrees Celsius to approximately 100 degrees Celsius to achieve a grind rate 602 that is included in a range of approximately 0.25 microns per minute to approximately 0.7 microns per minute. However, other values for the ranges are within the scope of the present disclosure. The use of deionized water in the grinding operation (without the use of a chemical etchant 124) may result in a grind rate 602 of approximately 0.05 microns per minute. However, other values are within the scope of the present disclosure.

As indicated above, FIG. 6 is provided as an example. Other examples may differ from what is described with regard to FIG. 6.

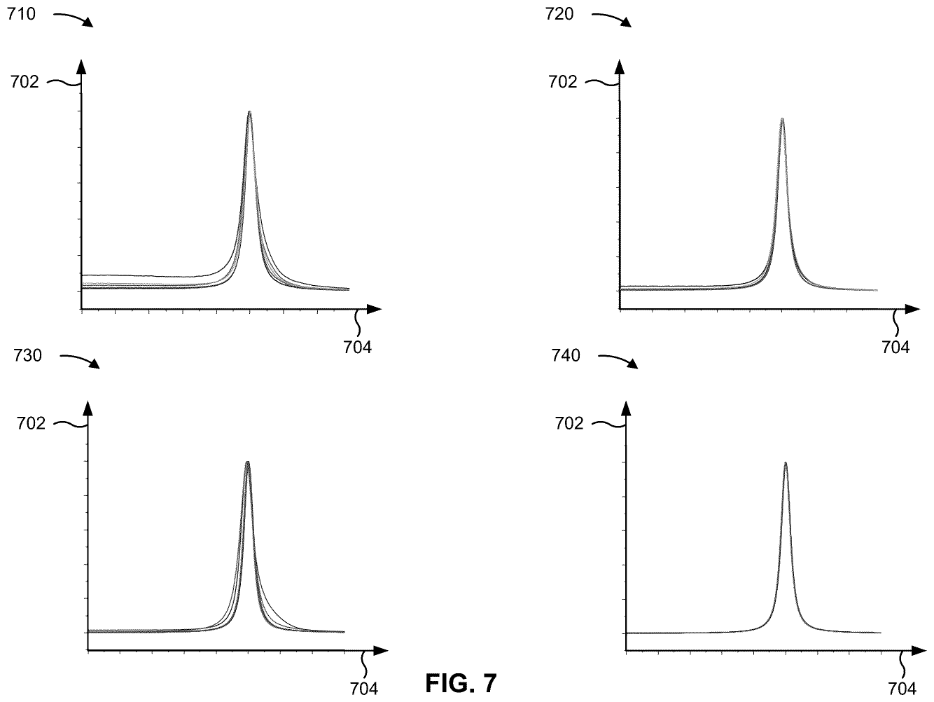

FIG. 7 is a diagram of example implementations of surface roughness for semiconductor substrates 106 processed by the substrate grinding tool 100 described herein. The example implementations of surface roughness for semiconductor substrates 106 processed by the substrate grinding tool 100 may be illustrated as light intensity 702 as a function of a shift in a Raman peak 704 due to inelastic scattering of light from the surface 112 of the semiconductor substrates 106.

An example implementation 710 may include an example surface roughness for a semiconductor substrate 106 processed by the substrate grinding tool 100 using deionized water in a grinding operation. Example implementations 720, 730, and 740 may each include an example surface roughness for a semiconductor substrate 106 processed by the substrate grinding tool 100 using a chemical etchant 124 in a grinding operation. The chemical etchant 124 may include a solution in which potassium hydroxide (KOH) is diluted in deionized water to approximately 30% of the total volume of the solution. The chemical etchant 124 in the grinding operation associated with the example implementation 720 may be heated to approximately 26 degrees Celsius. The chemical etchant 124 in the grinding operation associated with the example implementation 730 may be heated to approximately 70 degrees Celsius. The chemical etchant 124 in the grinding operation associated with the example implementation 740 may be heated to approximately 70 degrees Celsius and dispensed onto a semiconductor substrate 106 in the grinding operation for approximately 2 minutes.

In general, the use of the chemical etchant 124 in a grinding operation performed by the substrate grinding tool 100 to remove material from a semiconductor substrate 106 enables a lesser surface roughness to be achieved for the semiconductor substrate 106 relative to the use of deionized water. For example, the use of the chemical etchant 124 that is heated to approximately 26 degrees Celsius may achieve a Raman peak shift in absolution of approximately 0.09 reciprocal centimeters (cm⁻¹) for the semiconductor substrate 106 relative to the use of deionized water, which may achieve a Raman peak shift in absolution of approximately 0.134 cm⁻¹. As another example, the use of the chemical etchant 124 that is heated to approximately 26 degrees Celsius may achieve a full width at half maximum (FWHM) Raman peak shift (e.g., the distance between half the maximum value of the Raman peak) of approximately 3.84 for the semiconductor substrate 106 relative to the use of deionized water, which may achieve an FWHM Raman peak shift of approximately 4.086. However, other values are within the scope of the present disclosure.

As another example, the use of the chemical etchant 124 that is heated to approximately 70 degrees Celsius may achieve a Raman peak shift in absolution of approximately 0.035 cm⁻¹ for the semiconductor substrate 106 relative to the use of deionized water, which may achieve a Raman peak shift in absolution of approximately 0.134 cm⁻¹. As another example, the use of the chemical etchant 124 that is heated to approximately 70 degrees Celsius may achieve an FWHM Raman peak shift of approximately 3.53 for the semiconductor substrate 106 relative to the use of deionized water, which may achieve an FWHM Raman peak shift of approximately 4.086. However, other values are within the scope of the present disclosure.

As indicated above, FIG. 7 is provided as examples. Other examples may differ from what is described with regard to FIG. 7.

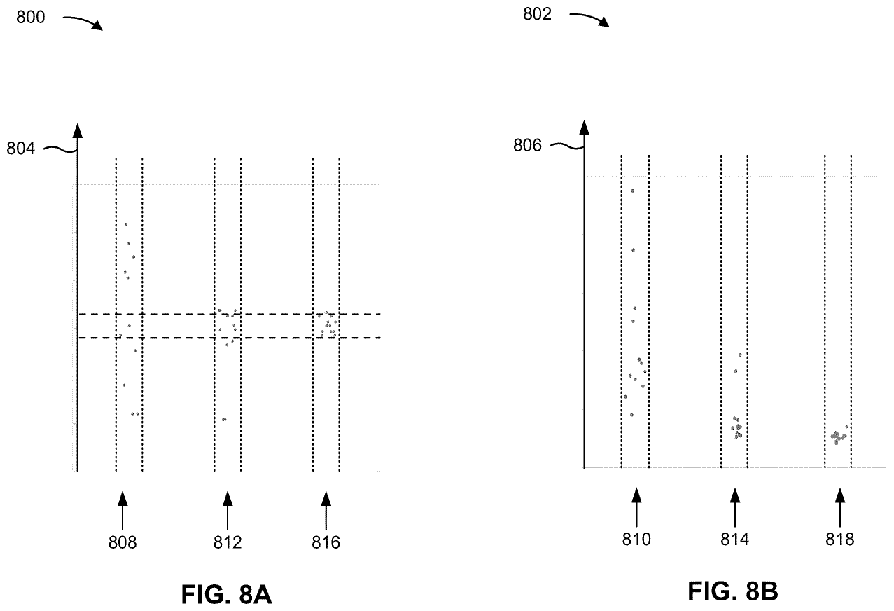

FIGS. 8A and 8B are diagrams of example implementations of surface roughness for semiconductor substrates 106 processed by the substrate grinding tool 100 described herein. FIG. 8A illustrates an example implementation 800 of Raman peak shift 804 for a plurality of example chemical etchants 124 that may be used in a grinding operation performed by the substrate grinding tool 100. FIG. 8B illustrates an example implementation 802 of FWHM 806 for Raman peak shifts of a plurality of example chemical etchants 124 that may be used in a grinding operation performed by the substrate grinding tool 100.

The plurality of example chemical etchants 124 may each include a solution in which potassium hydroxide (KOH) is diluted in deionized water to approximately 30% of the total volume of the solution. The chemical etchant 124 in the grinding operation associated with distributions 808 and 810 in FIGS. 8A and 8B, respectively, may be heated to approximately 26 degrees Celsius. The chemical etchant 124 in the grinding operation associated with distributions 812 and 814 in FIGS. 8A and 8B, respectively, may be heated to approximately 70 degrees Celsius. The chemical etchant 124 in the grinding operation associated with distributions 816 and 818 in FIGS. 8A and 8B, respectively, may be heated to approximately 70 degrees Celsius and dispensed onto a semiconductor substrate 106 in the grinding operation for approximately 2 minutes.

As shown in FIG. 8A, the distribution of Raman peak shift 804 generally decreases as the temperature of the chemical etchant 124 is increased. The distribution 808 may be greater relative to the distribution 812, and the distribution 812 may be greater relative to the distribution 816. In other words, the surface roughness that is achieved for semiconductor substrates 106 processed by the substrate grinding tool 100 may be lesser for greater temperatures of the chemical etchant 124 (and/or greater time durations of exposure of the semiconductor substrates 106 to the chemical etchant 124).

As shown in FIG. 8B, the distribution of FWHM 806 for Raman peak shifts generally decreases as the temperature of the chemical etchant 124 is increased. The distribution 810 may be greater relative to the distribution 814, and the distribution 814 may be greater relative to the distribution 818. In other words, the surface roughness that is achieved for semiconductor substrates 106 processed by the substrate grinding tool 100 may be lesser for greater temperatures of the chemical etchant 124 (and/or greater time durations of exposure of the semiconductor substrates 106 to the chemical etchant 124).

As indicated above, FIGS. 8A and 8B are provided as examples. Other examples may differ from what is described with regard to FIGS. 8A and 8B.

FIG. 9 is a diagram of example components of a device 900 described herein. The device 900 may correspond to one or more components included in the substrate grinding tool 100 described herein, such as the motor assembly 132 and/or the controller 134, among other examples. In some implementations, one or more components included in the substrate grinding tool 100 described herein, such as the motor assembly 132 and/or the controller 134 among other examples, may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

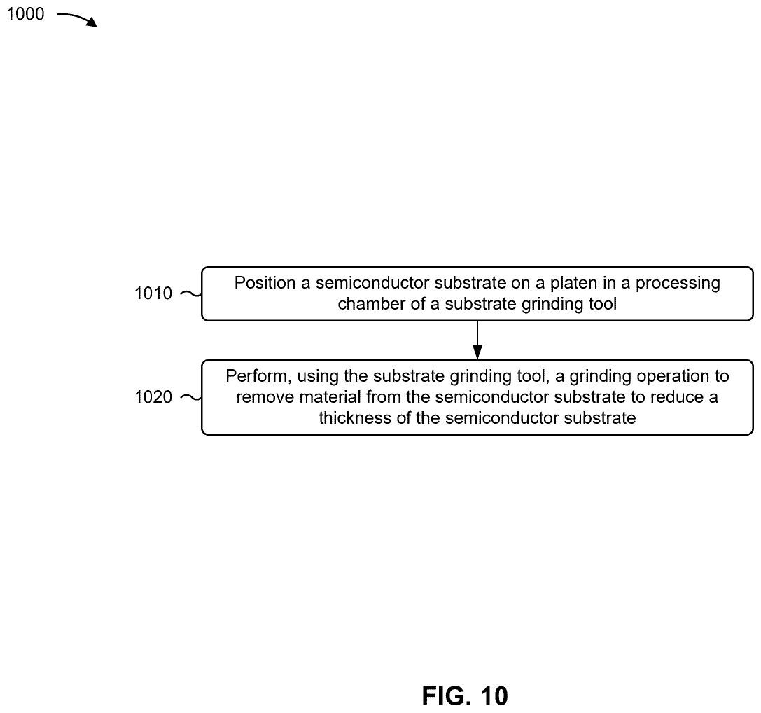

FIG. 10 is a flowchart of an example process 1000 associated with a grinding operation. In some implementations, one or more process blocks of FIG. 10 are performed by a substrate grinding tool (e.g., the substrate grinding tool 100). In some implementations, one or more process blocks of FIG. 10 are performed by another device or a group of devices separate from or including the substrate grinding tool 100, such as a controller (e.g., the controller 134), among other examples. Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include positioning a semiconductor substrate on a platen in a processing chamber of a substrate grinding tool (block 1010). For example, the substrate grinding tool 100 may position a semiconductor substrate 106 on a platen 104 in a processing chamber 102 of a substrate grinding tool 100, as described herein.

As further shown in FIG. 10, process 1000 may include performing a grinding operation to remove material from the semiconductor substrate to reduce a thickness of the semiconductor substrate (block 1020). For example, the substrate grinding tool 100 may perform a grinding operation to remove material from the semiconductor substrate 106 to reduce a thickness of the semiconductor substrate 106, as described herein. In some implementations, a chemical etchant 124 dispensed onto a surface 112 of the semiconductor substrate 106 during the grinding operation is used to reduce a surface roughness of the semiconductor substrate 106. In some implementations, a temperature of the chemical etchant 124 satisfies a temperature threshold.

Process 1000 may include additional implementations, such as any single implementation or any combination of implementations described below and/or in connection with one or more other processes described elsewhere herein.

In a first implementation, the semiconductor substrate 106 includes a silicon (Si) substrate, and the chemical etchant 124 includes potassium hydroxide (KOH).

In a second implementation, alone or in combination with the first implementation, the potassium hydroxide is included in a solution along with deionized water, and approximately 5% to approximately 40% of a total volume of the solution is the potassium hydroxide.

In a third implementation, alone or in combination with one or more of the first and second implementations, the chemical etchant 124 is dispensed onto the surface 112 of the semiconductor substrate 106 after a grinding device 114 of the substrate grinding tool 100 mechanically grinds the surface 112 of the semiconductor substrate 106 during the grinding operation.

In a fourth implementation, alone or in combination with one or more of the first through third implementations, a pH of the chemical etchant 124 is included in a range of approximately 10 to approximately 14.

In a fifth implementation, alone or in combination with one or more of the first through fourth implementations, the chemical etchant 124 is dispensed onto the surface 112 of the semiconductor substrate 106 while a grinding device 114 of the substrate grinding tool mechanically grinds the surface 112 of the semiconductor substrate 106 during the grinding operation.

In a sixth implementation, alone or in combination with one or more of the first through fifth implementations, the semiconductor substrate 106 is rotated on the platen 104 while the chemical etchant 124 is dispensed onto the surface 112 of the semiconductor substrate 106 to disperse the chemical etchant 124 across the surface 112 of the semiconductor substrate 106.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

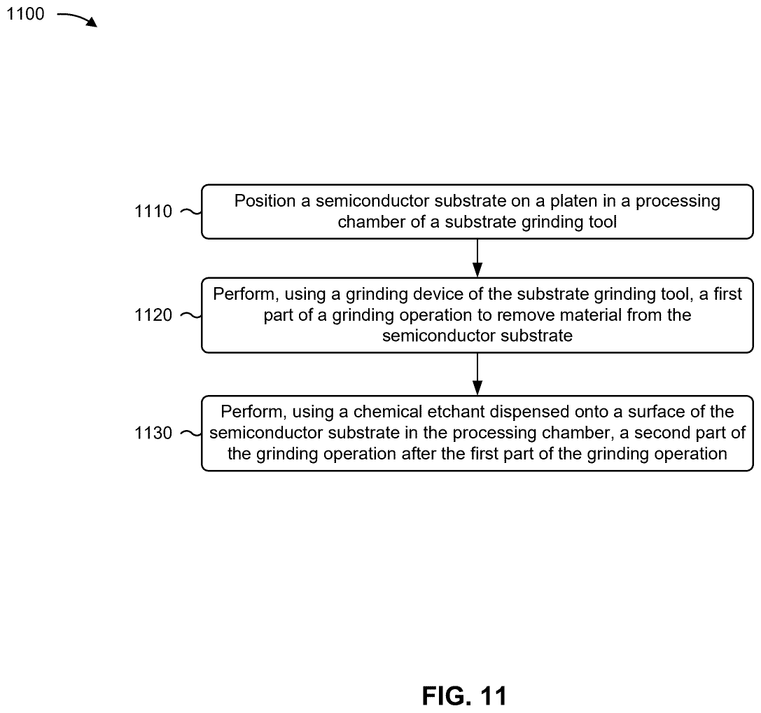

FIG. 11 is a flowchart of an example process 1100 associated with a grinding operation. The example process 1100 may include performing multiple parts of a grinding operation. In some implementations, one or more process blocks of FIG. 11 are performed by a substrate grinding tool (e.g., the substrate grinding tool 100). In some implementations, one or more process blocks of FIG. 11 are performed by another device or a group of devices separate from or including the substrate grinding tool 100, such as a controller (e.g., the controller 134), among other examples. Additionally, or alternatively, one or more process blocks of FIG. 11 may be performed by one or more components of device 900, such as processor 920, memory 930, input component 940, output component 950, and/or communication component 960.

As shown in FIG. 11, process 1100 may include positioning a semiconductor substrate on a platen in a processing chamber of a substrate grinding tool (block 1110). For example, the substrate grinding tool 100 may position a semiconductor substrate 106 on a platen 104 in a processing chamber 102 of a substrate grinding tool 100, as described herein.

As further shown in FIG. 11, process 1100 may include performing, using a grinding device of the substrate grinding tool, a first part of a grinding operation to remove material from the semiconductor substrate (block 1120). For example, the substrate grinding tool 100 may perform, using a grinding device 114 of the substrate grinding tool 100, a first part of a grinding operation to remove material from the semiconductor substrate 106, as described herein.

As further shown in FIG. 11, process 1100 may include performing, using a chemical etchant dispensed onto a surface of the semiconductor substrate in the processing chamber, a second part of the grinding operation after the first part of the grinding operation (block 1130). For example, the substrate grinding tool 100 may perform, using a chemical etchant 124 dispensed onto a surface 112 of the semiconductor substrate 106 in the processing chamber 102, a second part of the grinding operation after the first part of the grinding operation, as described herein. In some implementations, the chemical etchant 124 is dispensed onto the surface 112 of the semiconductor substrate 106 at a temperature that is included in a particular temperature range such that an etch rate of the chemical etchant 124, for etching the surface 112 of the semiconductor substrate 106, satisfies an etch rate threshold.

Process 1100 may include additional implementations, such as any single implementation or any combination of implementations described below and/or in connection with one or more other processes described elsewhere herein.

In a first implementation, the temperature range includes approximately 40 degrees Celsius to approximately 100 degrees Celsius.

In a second implementation, alone or in combination with the first implementation, the semiconductor substrate 106 includes a silicon (Si) substrate, and the chemical etchant 124 includes sodium hydroxide (NaOH).

In a third implementation, alone or in combination with one or more of the first and second implementations, performing the second part of the grinding operation includes performing the second part of the grinding operation using a combination of the chemical etchant 124 and the grinding device 114.

In a fourth implementation, alone or in combination with one or more of the first through third implementations, performing the second part of the grinding operation includes performing the second part of the grinding operation to reduce a surface roughness of the surface 112 of the semiconductor substrate 106.

In a fifth implementation, alone or in combination with one or more of the first through fourth implementations, the chemical etchant 124 includes potassium hydroxide (KOH).

In a sixth implementation, alone or in combination with one or more of the first through fifth implementations, the semiconductor substrate 106 is rotated on the platen 104 while the chemical etchant 124 is dispensed onto the surface 112 of the semiconductor substrate 106 to disperse the chemical etchant 124 across the surface 112 of the semiconductor substrate 106.

Although FIG. 11 shows example blocks of process 1100, in some implementations, process 1100 includes additional blocks, fewer blocks, different blocks, or differently arranged blocks than those depicted in FIG. 11. Additionally, or alternatively, two or more of the blocks of process 1100 may be performed in parallel.

In this way, a substrate grinding tool is configured to remove material from a semiconductor substrate in a grinding operation. In the grinding operation, the substrate grinding tool uses a combination of mechanical grinding and a chemical etchant to remove material from the semiconductor substrate. The chemical etchant may include a silicon etchant that is heated to a high temperature, which may increase the etch rate of the chemical etchant.

In this way, the use of the combination of mechanical grinding the chemical etchant may increase the grinding rate of the substrate grinding tool for grinding semiconductor substrates, which may increase the wafer per hour (WPH) processing throughput of the substrate grinding tool relative to the use of only mechanical grinding.

Moreover, the use of the combination of mechanical grinding and the chemical etchant may reduce surface damage and/or may reduce surface roughness for semiconductor substrates that are processed by the substrate grinding tool. This may reduce current leakage in one or more semiconductor devices formed on the semiconductor substrates and/or may reduce the likelihood of failure of one or more semiconductor devices formed on the semiconductor substrates, among other examples.

In addition, the reduced surface damage and/or reduced surface roughness for the semiconductor substrates may reduce the need for additional rework through additional chemical mechanical polishing (CMP) operations and/or additional etching operations. This may reduce the complexity of manufacturing semiconductor devices from the semiconductor substrates in the quantity of processing steps may be reduced for manufacturing semiconductor devices, the amount of time for manufacturing the semiconductor device may be reduced, and/or the cost of manufacturing the semiconductor device may be reduced, among other examples.

As described in greater detail above, some implementations described herein provide a method. The method includes positioning a semiconductor substrate on a platen in a processing chamber of a substrate grinding tool. The method includes performing, using the substrate grinding tool, a grinding operation to remove material from the semiconductor substrate to reduce a thickness of the semiconductor substrate, where a chemical etchant dispensed onto a surface of the semiconductor substrate during the grinding operation is used to reduce a surface roughness of the semiconductor substrate, and where a temperature of the chemical etchant satisfies a temperature threshold.

As described in greater detail above, some implementations described herein provide a method. The method includes positioning a semiconductor substrate on a platen in a processing chamber of a substrate grinding tool. The method includes performing, using a grinding device of the substrate grinding tool, a first part of a grinding operation to remove material from the semiconductor substrate. The method includes performing, using a chemical etchant dispensed onto a surface of the semiconductor substrate in the processing chamber, a second part of the grinding operation after the first part of the grinding operation, where the chemical etchant is dispensed onto the surface of the semiconductor substrate at a temperature that is included in a particular temperature range such that an etch rate of the chemical etchant, for etching the surface of the semiconductor substrate, satisfies an etch rate threshold.

As described in greater detail above, some implementations described herein provide a substrate grinding tool. The substrate grinding tool includes a processing chamber. The substrate grinding tool includes a platen, in the processing chamber, configured to support a semiconductor substrate. The substrate grinding tool includes a grinding device, in the processing chamber, that includes an abrasive configured to mechanically remove material from the semiconductor substrate. The substrate grinding tool includes a dispenser nozzle, in the processing chamber, configured to dispense a chemical etchant onto a surface of the semiconductor substrate to chemically etch the surface of the semiconductor substrate.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A substrate grinding tool, comprising:
a processing chamber;
a platen, in the processing chamber, configured to support a semiconductor substrate;
a grinding device, in the processing chamber, that includes an abrasive configured to mechanically remove material from the semiconductor substrate; and
a dispenser nozzle, in the processing chamber, configured to dispense a chemical etchant onto a surface of the semiconductor substrate to chemically etch the surface of the semiconductor substrate.

2. The substrate grinding tool of claim 1, wherein the dispenser nozzle is configured to dispense the chemical etchant at a temperature that is included in a range of approximately 40 degrees Celsius to approximately 100 degrees Celsius.

3. The substrate grinding tool of claim 1, wherein the dispenser nozzle is configured to dispense the chemical etchant onto the surface of the semiconductor substrate while the platen rotates the semiconductor substrate.

4. The substrate grinding tool of claim 1, wherein the dispenser nozzle is configured to dispense the chemical etchant onto the surface of the semiconductor substrate while the grinding device mechanically removes the material from the semiconductor substrate.

5. The substrate grinding tool of claim 1, wherein the dispenser nozzle is configured to dispense the chemical etchant onto the surface of the semiconductor substrate after the grinding device mechanically removes the material from the semiconductor substrate.

6. The substrate grinding tool of claim 1, wherein the dispenser nozzle is configured to dispense the chemical etchant onto the surface of the semiconductor substrate while the grinding device mechanically removes the material from the semiconductor substrate, and after the grinding device mechanically removes the material from the semiconductor substrate.

7. A tool, comprising:
a processing chamber;
a platen, in the processing chamber, configured to support a semiconductor substrate;
a grinding assembly, at least partially in the processing chamber, configured to, during a grinding operation and while the platen is being rotated, mechanically grind a surface of the semiconductor substrate to remove material from the surface of the semiconductor substrate; and
a dispenser nozzle, at least partially included in the processing chamber, configured to, during the grinding operation, dispense a chemical etchant onto the surface of the semiconductor substrate to chemically etch the surface of the semiconductor substrate.

8. The tool of claim 7, wherein the platen includes a chuck configured to secure the semiconductor substrate to the platen.

9. The tool of claim 7, wherein the grinding assembly comprises a grinding device including an abrasive configured to grind the surface of the semiconductor substrate.

10. The tool of claim 9, wherein the grinding assembly further comprises an arm configured to pivot the grinding device.

11. The tool of claim 10, wherein the arm is further configured to rotate the grinding device about an axis of the grinding device.

12. The tool of claim 7, wherein the chemical etchant is dispensed at or near a center of the semiconductor substrate.

13. The tool of claim 7, wherein a rotation of the semiconductor substrate causes the chemical etchant to flow radially outward from a center of the semiconductor substrate.

14. The tool of claim 7, further comprising:
a drive shaft configured to rotate the platen,
wherein at least one of the mechanically grinding the surface of the semiconductor substrate, or the dispensing of the chemical etchant onto the surface of the semiconductor substrate, is while the platen is being rotated.

15. A tool, comprising:
a controller, configured to:
transmit a first signal to rotate a platen configured to support a semiconductor substrate;
transmit a second signal to a grinding assembly to mechanically grind a surface of the semiconductor substrate to remove material from the surface of the semiconductor substrate; and
transmit a third signal to an etching assembly to chemically etch the surface of the semiconductor substrate.

16. The tool of claim 15, wherein the controller is further configured to:
receive a selection of a velocity for rotating the platen,
wherein the first signal indicates the velocity for rotating the platen.

17. The tool of claim 15, wherein the controller is further configured to:
receive a selection of a velocity for rotating the grinding assembly to grind the surface of the semiconductor substrate,
wherein the second signal indicates the velocity for rotating the grinding assembly.

18. The tool of claim 15, wherein the controller is further configured to:
receive a selection of a downforce of the grinding assembly on the surface of the semiconductor substrate,
wherein the second signal indicates the downforce of the grinding assembly.

19. The tool of claim 15, wherein the controller is further configured to:
transmit a fourth signal to the etching assembly to heat a chemical etchant to chemically etch the surface of the semiconductor substrate.

20. The tool of claim 15, wherein the controller is further configured to:
transmit, after transmitting the second signal and the third signal, a fourth signal to modify one or more parameters of the grinding assembly.
